(19) United States
(12) Patent Application Publication
(10) Pub. No.: US 2026/0068260 A1
(43) Pub. Date: Mar. 5, 2026

(54) DRAIN EXTENDED TRANSISTOR WITH FIELD PLATES

(71) Applicant: Texas Instruments Incorporated, Dallas, TX (US)

(72) Inventors: Ali Saadat, Santa Clara, CA (US); Henry Litzmann Edwards, Garland, TX (US); Vijay K. Reddy, Plano, TX (US)

(21) Appl. No.: 18/816,880

(22) Filed: Aug. 27, 2024

(51) Int. Cl. H01L 29/40; H01L 29/08; H01L 29/423; H01L 29/49; H01L 29/66; H01L 29/78

(52) U.S. Cl. CPC H10D 64/111; H10D 30/0281; H10D 30/655; H10D 62/159; H10D 64/514; H10D 64/661

(57) ABSTRACT

A transistor includes a body region and a drain drift region of opposite first and second conductivity types in a semiconductor layer, as well as a gate dielectric layer including first and second portions of a uniform thickness on the semiconductor layer, wherein the first portion is located over a junction between the body region and the drain drift region and the second portion is located over the drain drift region. The transistor includes a gate electrode on the first portion of the gate dielectric layer, a drain region in the drain drift region and having the second conductivity type, and a field plate located on the second portion of the gate dielectric layer and disposed between the gate electrode and the drain region.

### BACKGROUND

Drain extended transistors are used in high voltage applications that require high breakdown voltage ratings and efficient operation, such as a low side switch in a switching power supply to provide low drain-source resistance (RDSON) during the on-state, along with the ability to block or withstand high off-state voltages between the drain and the source or gate. The extended drain architecture has a lightly doped drift region that allows carrier depletion under drain reverse bias so that the drain can block current flow during high voltage operation. The polysilicon gate can be extended above the drift region to improve drift region charge balance. However, this approach leaves a nonuniform electric field with peaks in the drift region during off-state operation, such as a peak under the end of the polysilicon field plate. The non-uniform electric field reduces the breakdown voltage from an ideal value and can lead to sub-optimal breakdown voltage performance that can only be addressed by increasing the lateral drift region length to accommodate a required drain blocking voltage in the off-state within the limits of semiconductor breakdown strength. Increasing the drift region length to help voltage breakdown performance inhibits efforts to reduce circuit area and increases the on-state drain-source resistance (RDSON) of the transistor as the carriers have more material to travel through.

### SUMMARY

In one aspect, a semiconductor device includes a drain extended transistor having a semiconductor layer over a semiconductor substrate, the semiconductor layer including a body region having a first conductivity type and a drain drift region having a second, opposite, conductivity type, a gate dielectric layer over the body region and extending over a junction between the body region and the drain drift region, a gate electrode over a first portion of the gate dielectric layer, a drain region having the second conductivity type in the drain drift region, the drain region having a dopant density greater than a dopant density of the drain drift region, and a field plate located over a second portion of the gate dielectric layer and between the gate electrode and the drain region.

In another aspect, a transistor includes a body region in a semiconductor layer and having a first conductivity type, a drain drift region in the semiconductor layer and having a second, opposite, conductivity type, a continuous gate dielectric layer including first and second portions of uniform thickness on the semiconductor layer, the first portion of the gate dielectric layer located over a junction between the body region and the drain drift region. The transistor includes a gate electrode over the first portion of the gate dielectric layer, a drain region in the drain drift region and having the second conductivity type, a field plate located over the second portion of the gate dielectric layer and between the gate electrode and the drain region, and a circuit configured to provide a non-zero field plate bias voltage to the field plate that is different from a voltage of the gate electrode.

In a further aspect, a method includes forming a gate dielectric layer of uniform thickness directly on and contacting a semiconductor layer, forming a gate electrode over a first portion of the gate dielectric layer, and forming a field plate over a second portion of the gate dielectric layer.

### BRIEF DESCRIPTION OF THE DRAWINGS

FIG. 1 is a partial sectional side elevation view of a semiconductor device including a drain extended transistor with a biased field plate taken along line 1-1 in FIG. 1A.

FIG. 1A is a partial top plan view of the semiconductor device of FIG. 1.

FIG. 2 is a flow diagram of a method.

FIG. 2A is a flow diagram of a method of fabricating a semiconductor device.

FIG. 3 is a partial sectional side elevation view of an extended drain transistor model with a graph of off-state drift region voltage as a function of lateral distance from the source to the drain and a graph of voltage as a function of vertical depth.

FIG. 4 is a graph of field plate bias voltage as a function of lateral distance from the source to the drain with an ideal linear modeled curve and a simulated single biased field plate lateral position and width.

FIG. 5 is a partial sectional side elevation view of another semiconductor device including a drain extended transistor with three biased field plates.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”. Unless otherwise stated, “about,” “approximately,” or “substantially” preceding a value means+/−10 percent of the stated value.

One or more operational characteristics of various circuits, systems and/or components are hereinafter described in the context of functions which in some cases result from configuration and/or interconnection of various structures when circuitry is powered and operating. One or more structures, features, aspects, components, etc., may be referred to herein as first, second, third, etc., such as first and second terminals, first, second, and third, wells, etc., for case of description in connection with a particular drawing, where such are not to be construed as limiting with respect to the claims. Various disclosed structures and methods of the present disclosure may be beneficially applied to manufactured electronic apparatus such as an integrated circuit. While such examples may be expected to provide various improvements, no particular result is a requirement of the present disclosure unless explicitly recited in a particular claim.

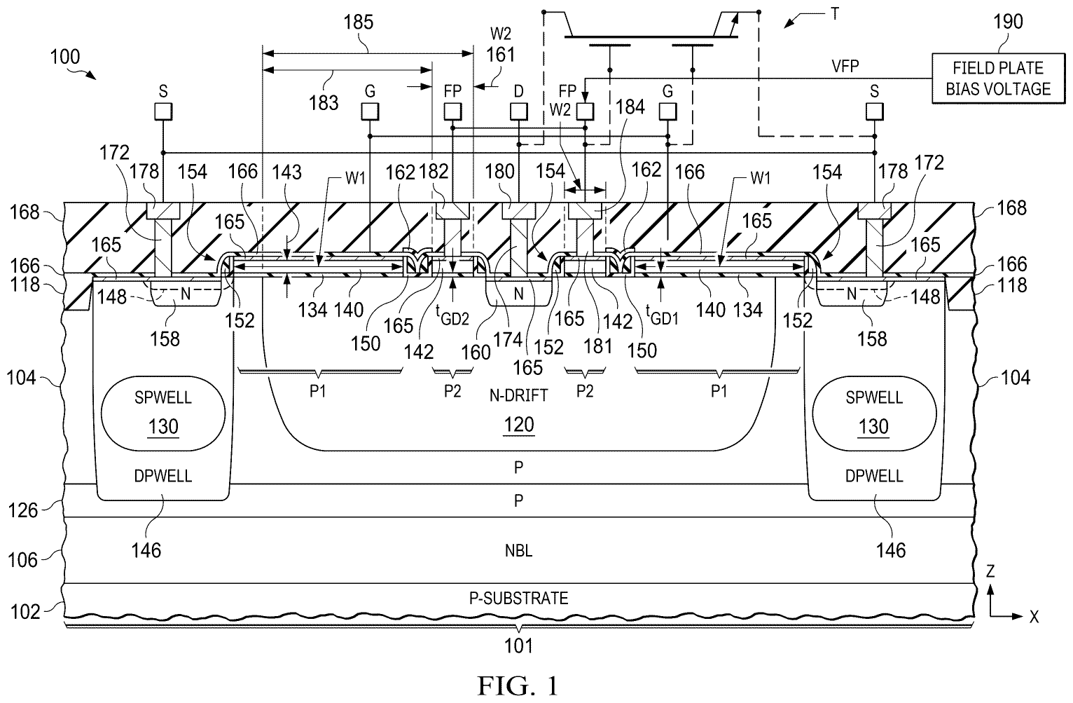

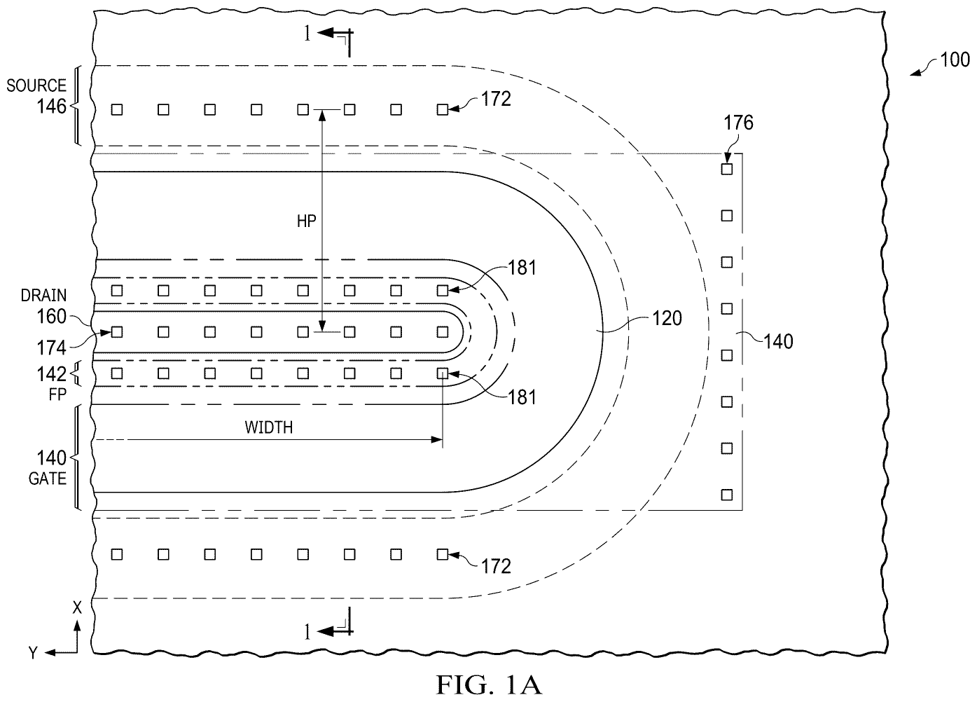

FIGS. 1 and 1A show a semiconductor device 100 that includes a drain extended transistor 101 with a biased field plate 142 having a lateral position and bias voltage determined by device model adjustment through simulation. The biased field plate 142 may also be referred to as a biased drain field plate. Described examples can enable improved off-state drift region electric field profile uniformity while maintaining good breakdown voltage performance with small half pitch dimensions without increasing the drift region length while maintaining low on-state resistance. Although scaling half pitch dimensions may be limited along the drift region by semiconductor breakdown strength and reducing the on-state resistance may be limited by the doping density and carrier mobility in the drift region, field plate positioning and biasing can be tailored for a given design specification through simulation and iterative model adjustment to provide benefits beyond the performance of a gate voltage biased field plate.

The semiconductor device 100 and the transistor 101 thereof can be used in compact low voltage applications, such as transistors operating at approximately 10-15 V or less, although not a requirement of all possible implementations. The semiconductor device 100 is shown in an example three-dimensional space with a first direction X (FIGS. 1 and 1A), a perpendicular (orthogonal) second direction Y (FIG. 1A), and a third direction Z (FIG. 1) that is perpendicular (orthogonal) to the respective first and second directions X and Y. Structures or features along any two of these directions are orthogonal to one another. The example drain extended transistor 101 is an n-channel laterally diffused metal oxide semiconductor (LDMOS) transistor. FIG. 1 shows a schematic representation of the drain extended transistor 101 labeled “T” with indicated connections to a gate G, a drain D and a source S as well as a field plate FP laterally disposed between the gate G and the drain D. In another implementation, p-channel LDMOS transistors can be formed when n-doped regions are substituted by p-doped regions and p-doped regions are substituted by n-doped regions in another implementation. In one example, further electronic components (not shown) may be provided in the semiconductor device 100, such as a second drain extended transistor interconnected with the illustrated transistor 101 in a half bridge circuit in a packaged integrated circuit with terminals or leads providing external connections to some or all of the transistor terminals. In some implementations, further circuitry can be included, such as gate driver circuits (not shown), switching control timing circuitry, etc., in a single integrated circuit for use in high voltage switching applications such as power conversion systems, transceivers, etc.

As further shown in FIG. 1, the example semiconductor device 100 includes a semiconductor substrate 102, such as including silicon or other semiconductor material from a starting wafer doped with impurities of a first conductivity type (e.g., P-type), such as a silicon (Si) or other semiconductor wafer (e.g., silicon carbide or SiC, gallium nitride or GaN, etc.), a silicon on insulator (SOI) wafer, etc. The semiconductor device 100 in one example includes a semiconductor layer 104 (e.g., p-type epitaxial silicon) that extends over the semiconductor substrate 102 and includes a body region 104 having the first conductivity type (e.g., P-type). An n-type buried layer (NBL) 106 extends under the semiconductor layer 104 and has an opposite second conductivity type (e.g., N-type). In one example, an isolation structure including shallow trench isolation 118 extends around the outer periphery of the transistor 101 along and into the top side of the semiconductor layer 104.

The semiconductor device 100 includes a drain drift region 120 (e.g., labelled “N-DRIFT” in FIG. 1) having the second conductivity type and extending in the body region 104. A gate dielectric layer 134 extends over the drain drift region 120. The gate dielectric layer 134 in one example is or includes silicon dioxide (e.g., SiO₂) of any suitable stoichiometry. Other dielectric materials can be used in other examples, such as high-k dielectrics, nitride, etc., of any suitable, approximately uniform equivalent oxide thickness (EOT). As shown in FIG. 1A, the example drain extended transistor has a finger or racetrack shape with a center drain finger (e.g., labelled “D” in FIG. 1 and “DRAIN” in FIG. 1A), a polysilicon gate (e.g., labelled “G” in FIG. 1 and “GATE” in FIG. 1A) that encircles the drain, and a source (e.g., labelled “S” in FIG. 1 and “SOURCE” in FIG. 1A) that encircles the gate. In this or other examples, the transistor can include further drain-centered finger or racetrack structures (not shown). In these or other implementations, the transistor can include one or more source-centered finger or racetrack structures and/or one or more gate-centered finger or racetrack structures (not shown).

As further shown in FIG. 1, the example semiconductor device 100 can also include a p-type buried layer 126 (e.g., labelled “P”, also referred to as a pRESURF layer) with the first conductivity type and a dopant concentration greater than the body region 104. In one example, the body region 104 of the semiconductor layer includes a shallow well 130 (e.g., labeled “SPWELL” in FIG. 1) below the source S, with the first conductivity type (e.g., p-type) and a dopant density higher than that of the body region 104. The shallow well 130 increases a base doping level of the body region 104 to help suppress a parasitic lateral NPN bipolar transistor formed by an N+ source-p-body-N+ drain D, which may limit high current operation for the LDMOS transistor 101, thus restricting the safe operating area (SOA) of the LDMOS transistor 101.

The gate dielectric layer 134 also extends over a junction between the body region 104 and the drain drift region 120 and has a racetrack shape that extends over a portion of the body region 104 (FIG. 1). The gate dielectric layer 134 extends over the channel and an interface or junction between the p-type body region 104 and the n-type drift region 120 underneath a portion of the gate fingers or racetrack G. As further shown in FIGS. 1 and 1A, a polysilicon gate electrode 140 extends over the gate dielectric layer 134 above the drift region 120. The gate dielectric layer 134 in certain examples can be designed with respect to material and thickness for a logic level low voltage circuit, such as 5 V or 3.3 V logic transistors. In certain examples, the gate dielectric layer 134 has a uniform thickness and is thin, such as approximately 200 Å or less, although not a requirement of all possible implementations. Certain examples, moreover, can include a gate dielectric layer 134 having a thickness as small as approximately 10-15 Å, and other suitable examples include a gate dielectric thickness of approximately 20-200 Å, such as approximately 100 Å. In these or other examples, high dielectric constant (e.g., high K) dielectric material can be used for the gate dielectric layer 134, although not a requirement of all possible implementations. The use of very thin gate dielectric layers 134 may increase the risk of gate tunneling and affect the reliability and threshold voltage of the transistor 101.

The transistor 101 has a biased field plate 142, which may also be referred to as a biased drain field plate, which is located over the gate dielectric layer 134. The biased field plate 142 in this example also has a racetrack shape (e.g., labelled “FP” in FIGS. 1 and 1A). The biased field plate 142 is laterally spaced apart from the gate electrode 140 and is positioned laterally between the gate electrode 140 and the transistor drain. The field plate 142 is conductively connected to a biasing circuit (not shown) that provides a field plate bias voltage to the field plate 142 in powered operation of the semiconductor device 100. The illustrated example includes a single biased field plate 142. In other implementations (e.g., FIG. 5 below), two or more biased field plates can be provided that are spaced apart from one another and positioned laterally between the gate G and the drain D, with corresponding field plate dimensions and positions as well as field plate bias voltages determined according to an adjusted device model as described further below.

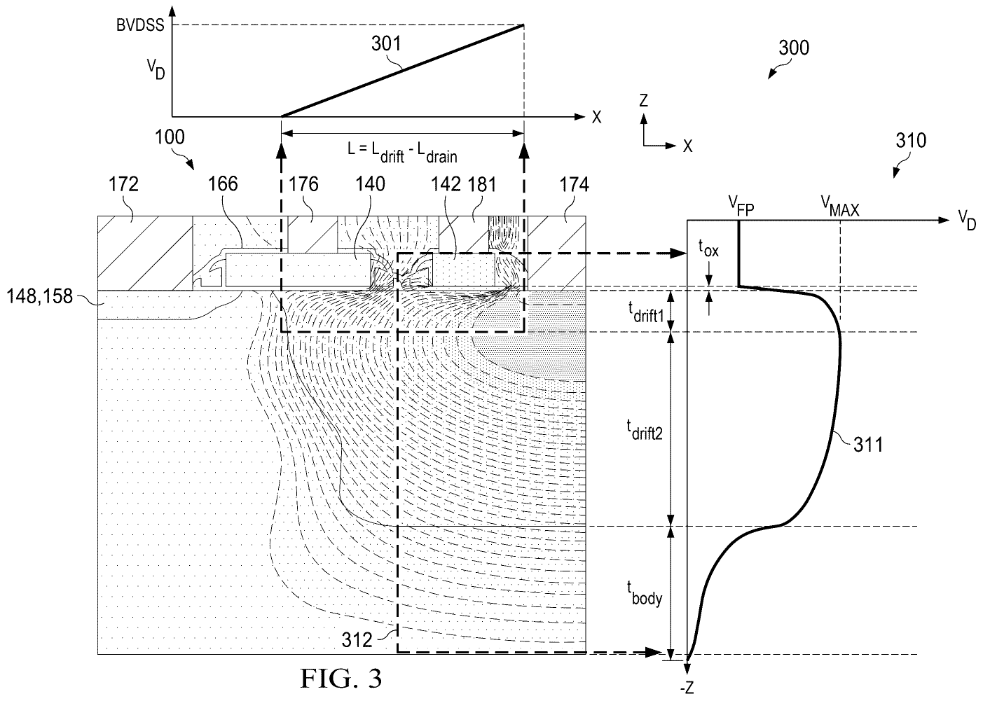

In one example, the field plate 142 is or includes polycrystalline silicon and can be formed and patterned concurrently with the gate electrode 140. The gate dielectric layer 134 extends over the body region 104 and extends over a junction between the body region 104 and the drain drift region 120. The gate electrode 140 extends over a first portion P1 of the gate dielectric layer 134 as shown in FIG. 1. The field plate 142 is located over a second portion P2 of the gate dielectric layer 134 and between the gate electrode 140 and the drain region 160. In one example, the first and second portions P1 and P2 of the gate dielectric layer 134 are formed concurrently. In this or another example, the first and second portions P1 and P2 of the gate dielectric layer 134 are spaced apart from one another. In another example, the first and second portions P1 and P2 of the gate dielectric layer 134 can be connected to one another—e.g., as depicted in FIG. 3. In one example, the first portion P1 of the gate dielectric layer 134 has a first width W1 (FIG. 1) that corresponds to an entire width (e.g., a lateral dimension) of the gate electrode 140, and the second portion P2 of the gate dielectric layer 134 has a second width W2 that corresponds to an entire width (e.g., a lateral dimension) of the field plate 142. The first portion P1 of the gate dielectric layer 134 in one example has a first thickness t_{GD1} and the second portion P2 of the gate dielectric layer 134 has a second thickness t_{GD2}. In the illustrated example, the first and second thicknesses t_{GD1} and t_{GD2} are approximately equal (e.g., within +/−10% of one of other as measured by an average thickness across the respective portions P1 and P2). In this or another example, the first and second thicknesses t_{GD1} and t_{GD2} are approximately 200 A or less. In certain examples, the first and second thicknesses t_{GD1} and t_{GD2} are approximately 20 A or more. The gate dielectric layer 134 in one example is or includes silicon dioxide (SiO₂). The gate dielectric layer 134 in certain examples can be a continuous structure of uniform thickness t_{GD1}, t_{GD2} including the respective first and second portions P1 and P2. Unlike drain extended transistors having a thick field oxide over the drift region, the gate dielectric thickness t_{GP2} in the second portion P2 is approximately equal to the gate dielectric thickness t_{GD1} in the first portion P1. In the illustrated example, the second portion P2 of the gate dielectric layer 134 is directly on and contacting the semiconductor layer 104, and the field plate 142 is directly on and contacting the second portion P2 of the gate dielectric layer 134.

The example drain extended transistor 101 also includes a source with a p-type deep well region 146 having the first conductivity type (e.g., labelled “DPWELL” in FIG. 1) that extends through and below the p-type shallow well 130. The p-type deep well region 146 extends to the top side of the body region 104 and connects to the p-type buried layer 126. An n-type well region 148 extends along the top side of the p-type deep well region 146 and has the second conductivity type. The example semiconductor device 100 also includes sidewall spacer structures 154 along the lateral sides of the gate electrode 140 and the field plate 142. The sidewall spacers 154 in one example include an oxide layer 150 and a nitride layer 152 formed by deposition and anisotropic etching. The sidewall spacers 154 overlap an edge of the gate dielectric layer 134 adjacent to the drain region. In another example, a nitride layer 152 may be deposited across the surface of the wafer and etched to form a nitride-only sidewall spacer 154. The transistor 101 has a source region 158 with the second conductivity type (N-type) in the p-type deep well 146, where the source region 158 can have a smaller depth than the n-type well region 148.

The transistor drain includes a drain region 160 with the second conductivity type extending along and into the top side of the drain drift region 120 in the body region 104 and the drain region 160 is laterally encircled by the field plate 142. The field plate 142 is spaced apart from, and extends laterally between, the gate electrode 140 and the drain region 160. The drain region 160 has a dopant density greater than the dopant density of the drain drift region 120. The gate dielectric layer 134 extends toward the drain region 160 and has a thickness t_{GD} (e.g., approximately equal to the gate dielectric thicknesses t_{GD1} and t_{GD2}. The field plate 142 in one example is electrically biased at a non-zero field plate bias voltage with respect to the substrate 102 or with respect to the source. In one example, the field plate 142 extends laterally between the drain region 160 and the gate by a field plate width dimension 161 (FIG. 1). As shown in FIG. 5 below, for example, one or more field plates can extend partially or entirely over portions of the gate dielectric layer 134 in other implementations.

The semiconductor device 100 in one example has a silicide blocking layer 162 (FIG. 1) that is or includes one or more sublayers of an oxide, a nitride, an oxynitride, or combinations thereof. The silicide blocking layer 162 in one example extends over the sidewall spacers 154 between the gate G and the biased field plate FP. In the illustrated example, the gate electrode 140 extends over the gate dielectric layer 134 and the gate electrode 140 is laterally spaced apart from the field plate 142 by a portion of the silicide blocking layer 162 that extends on the sidewall spacer structures 154. The sidewall spacer on the sidewall of the field plate 142 extends to the drain region 160.

The semiconductor device 100 also includes a metal silicide layer 165 that extend along upper sides of the deep well region 146 of the source and of the drain region 160 to facilitate low resistance electrical connection to the source and drain terminals of the transistor 101. In addition, a metal silicide layer 165 can be provided for low resistance electrical connection to the biased field plate 142 and to the gate electrode 140 by conductive metal (e.g., tungsten) contacts including gate contacts in a gate contact region at the lateral ends of the finger structure (FIG. 1A). The semiconductor device 100 also includes a nitride etch stop layer 166 that extends over portions of the metal silicide 165, the sidewall spacers 154, and the silicide blocking layer 162.

The semiconductor device 100 can include a single or multilevel metallization structure, with a pre-metal dielectric 168 (PMD), conductive metal (e.g., tungsten) contacts 172 and 174 for the source and the drain (FIGS. 1 and 1A), gate contacts 176 (FIG. 1A), and field plate contacts 181 (FIGS. 1 and 1A). The illustrated portion of the metallization structure in FIG. 1 also shows metal interconnects 178 and 180 conductively coupled to the respective source and drain contacts 172 and 174, as well as metal interconnects 182 and 184 coupled to the field plate contacts 181, and similar metal interconnects (not shown) are coupled to the gate contacts 176 for electrical connection to the various terminals of the transistor 101 in the metallization structure. The metal interconnects 182 and 184 allow electrical connection of a bias voltage circuit (not shown) to bias the field plates 142 and a non-zero field plate bias voltage may be applied during operation of the semiconductor device 100.

The semiconductor device 100 in one example includes a field plate voltage bias circuit 190 (FIG. 1) that is configured when the semiconductor device 100 is powered and operating to provide a non-zero field plate bias voltage VFP to the field plate 142 that is different from the voltage of the gate electrode 140. Other implementations can include more than one biased field plate position between the gate and the drain, which are individually biased with different field plate bias voltages that are different from the gate voltage. In one example, a biasing circuit provides the respective field plate bias voltages to maintain monotonic voltage increase of the field plate segments in the direction from the source to the drain such that the field plates shape the potential in the drift region 120 to fall approximately uniformly from drain to source. This can benefit off-state operation with the gate-to-source voltage at or near zero to help increase the breakdown voltage (BV) of the device, although not a requirement of all possible implementations.

Any suitable bias circuit 190 can be used for single or multiple biased field plate implementations, for example, a string of diodes connected in series with one another such as Zener diodes, source/drain-to-well diodes, lateral avalanche diodes, diode-connected bipolars, etc. (not shown). In other implementations passive (e.g., resistor based circuitry) and/or active (e.g., diode-connected transistors) may be used to bias the field plate 142 and/or a string of such circuits can be used to bias multiple field plates 142, for example to engineer temperature coefficient matching. In certain implementations (not shown), the bias circuit 190 can include a bias source applied to a diode before the first field plate 142 (nearest the gate) and back-to-back diodes may be added between the last field plate 142 and the drain, permitting the entire string of field plates to be biased during the transistor on-state, reducing RDSON.

In this or another example, the diode before the first field plate 142 nearest the gate may be tied to the gate or to the source or other suitable voltage supply node for simplicity if elevated on-state field plate biasing is not desired. In various implementations, the number of field plates may be varied to choose the drain voltage rating of the device, and the biasing of the field plate facilitates high breakdown voltage rating without having to increase the half pitch of the transistor 101. In multiple field plate implementations, moreover, the field plate width and spacing may be the same, although not a requirement of all possible implementations. In addition, the field plate-to-field plate voltage drops may be approximately equal, although not a requirement of all possible implementations.

In operation, the extended drain of the transistor 101 provides a relatively lightly doped drift region to extend the high voltage drain away from the edge of the channel region and the planar drift region can be used to increase the reverse blocking voltage. For even higher drain voltage rating, the drain side of the gate polysilicon is spaced from the drift region 120 by the gate dielectric layer 134 to facilitate more complete depletion of the drift region. Reduced surface field (RESURF) profiled doping can be used for full reverse bias depletion of the drift region. The drift region doping level or dopant concentration in certain examples can be higher near the connection to the transistor channel region to mitigate channel hot carrier injection into the gate and enhance the transistor reliability. In addition, the biased field plate 142 facilitates enhanced uniformity of the electric field in the drift region 120 below the gate dielectric layer 134 in the off-state of the transistor 101 to facilitate good breakdown voltage performance of the transistor 101 without adversely impacting the on-state drain-source resistance and without having to increase the lateral length of the drift region along the first direction X.

In power switching circuits, such as DC-DC converters, a high-side switch and a low-side switch may be fabricated as drain extended transistors and a source/back gate terminal of the high-side device can be isolated from circuit ground to facilitate high-voltage operation. In addition, shrinking geometries and alignment tolerances of advanced semiconductor manufacturing processes increase the performance impact of non-uniformities such as center-edge differences in device structure locations. Scaling drain extended transistors to reduce the half pitch dimension along the first direction X and/or design of transistors with a fixed half pitch dimension to facilitate higher breakdown voltage ratings can inhibit the ability to balance off-state breakdown voltage performance with low on-state drain-source resistance. The biased field plate 142, whether a single instance or multiple field plates can be configured as a contact field plate fabricated for hot carrier injection improvement in operation of the transistor 101, for example, to promote reduction of the specified on resistance degradation without substantially affecting the breakdown voltage of the transistor 101.

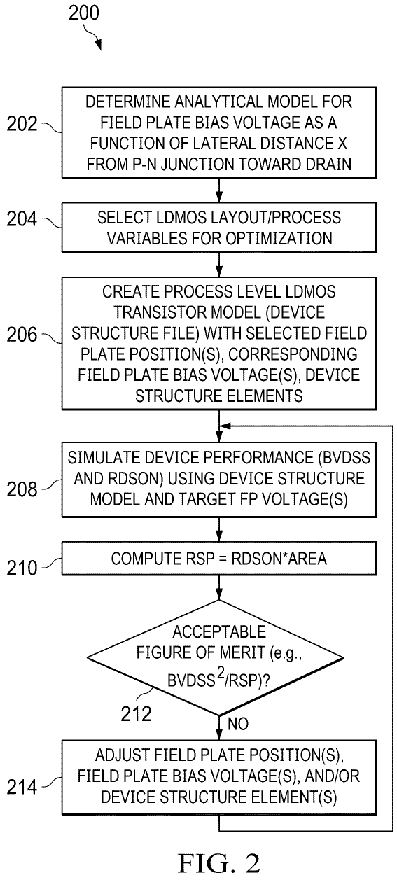

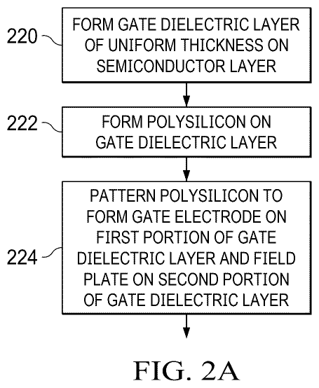

Referring also to FIG. 2, the improved electric field uniformity in the transistor off-state can be tailored for a given design of the field plate width dimension 161, the position of the lateral edges of the field plate 142 (e.g., the distances 183 and 185 in FIG. 1) from the body to drift region p-n junction and/or the bias voltage applied to the field plate 142 in operation, along with other structural and process values of the transistor 101 and the fabrication thereof. FIG. 2 shows a method 200 which can be used in the design and/or manufacturing (e.g., fabrication) of the semiconductor device 100 and the transistor 101 or other devices having one or more biased field plate drain extended transistors.

The method 200 in one example can be used for designing a given implementation of the drain extended transistor 101, for example, to provide approximately linear distribution of electric field along the lateral length of the drift region along the first direction X by the sizing, positioning and biasing of the biased field plate 142. The method 200 can also be used in connection with other transistor designs having more than one biased field plate and more than one corresponding field plate bias voltages (e.g., FIG. 5 below). The method 200 provides an adjusted device model that can be used to fabricate a drain extended transistor (e.g., transistor 101 above) with a drain extended transistor drift region with enhanced off-state electric field profile uniformity, enabling optimally small drift length (e.g., which may be limited along the drift region by semiconductor breakdown strength) along with optimally low on-state resistance (e.g., which may be limited by the doping density and carrier mobility in the drift region). In the example transistor 101 of FIGS. 1 and 1A, the gate dielectric layer 134 extends over the drain drift region 120 from the gate dielectric layer 134 toward the drain region. In this example, moreover, the biased field plate 142 is located over the gate dielectric layer 134 and laterally positioned between the gate electrode 140 and the drain region 160.

In one example implementation of the method 200, the position, dimensions, and/or bias voltage of the field plate 142 is/are determined by adjusting the transistor device model based on simulated performance of the drain extended transistor 101 using the device model. At 202 in FIG. 2, the method 200 includes determining an analytical model for the field plate bias voltage as a function of lateral distance (e.g., along the first direction X in FIG. 1) from the p-n junction of the source 148, 158 to the p-type body 104 toward the drain. In reference to FIG. 1 above, the example field plate 142 has a first lateral end spaced by the distance 183 from the body to drift region p-n junction along the first direction X, and the opposite second lateral end of the field plate 142 is spaced by the distance 185 from the body to drift region p-n junction, where the difference between the distances 183 and 185 is the width dimension 161 (e.g., lateral width) of the field plate 142.

The analytical modeling at 202 and FIG. 2 in one example includes expression in the form of an analytical equation determining the field plate (FP) potential/position for a given LDMOS device. In one example, the analytical equation is a linear equation (1):

$$VFP ( x ) = f ( x ) = ax + b , \qquad ( 1 )$$

where “a” and “b” are dependent on the dopant concentration ND of the drift region 120, the thickness t_{GD} of the gate dielectric layer 134 along the third direction Z (t_{GD} in FIG. 1), the half pitch dimension of the transistor 101 (e.g., HP in FIG. 1A), and potentially other process and/or structure level parameters. In some examples, “a” and “b” can vary based on a voltage rating of a given device and/or based on a different manufacturing facility or process. The analytical equation of the device model determines the initial inputs to start field plate position and/or biasing voltage optimization experiments using simulation and one or more iterations of device model adjustment based on the simulation. In one implementation, final biasing and position of the field plate 142 can be determined by sufficient trials of TCAD device simulation, as estimates and approximations made for the drift doping consideration and gate dielectric thickness top through analytical derivations at 202.

FIG. 3 shows the example extended drain transistor of the semiconductor device 100 with the graph 300 showing the ideal linear curve 301 of off-state drift region voltage as a function of lateral distance along the first direction X from the source to the drain and the graph 310 shows the simulated voltage curve 311 as a function of vertical depth along the third direction (e.g., −Z), with simulated equal potential lines illustrated in the off-state. As shown in a graph 300 in FIG. 3, the linear equation in one example provides a linear breakdown voltage VB curve 301 (also referred to as BV or BVDSS) as a function of the distance along a length L including the length L_{drift} minus the length L_{drain} in the first direction X between the junction (e.g., the body to drift region p-n junction) and the drain of the modeled drain extended transistor 101. In the example of FIG. 3, the contacts are illustrated as modeled (e.g., 172, 174, 176, 181) but do not need to all appear in the illustrated section, for example, where the gate contacts 176 in one example are at the end of the finger structure as shown in FIG. 1A and are not in the same section as the other contacts 172, 174 and 181. FIG. 3 also includes a graph 310 with a curve 311 that shows the vertical voltage drop in the third direction Z simulated along a vertical section line 312 that extends through the field plate 142 as shown in FIG. 3, and which includes the thickness tₒₓ of that portion of the gate dielectric layer 134 (labeled “t_{GD}” in FIG. 1), the thickness t_{drift} of the top or first portion of the drift region 120 the thickness t_{drift2} of the bottom or second portion of the drift region 120, and the thickness t_{body} of the p-type body 104 below the drift region 120.

The curve 311 in the graph 310 includes a maximum voltage Vₘₐₓ given by the following equation (2):

$${V}_{max} = {V}_{FP} ( x ) + Δ {V}_{top} = Δ {V}_{bottom} , \qquad ( 2 )$$

where ΔVₜₒₚ is the voltage drop in the gate dielectric 134+ the voltage drop in the top side of the drift region 120, and ΔV_{bottom} is the voltage drop in the bottom side of the drift region 120+ the voltage drop in the body/epi region 104. In one example, the analytical derivation includes the following equations:

$${V}_{FP} ( x ) = {V}_{max} - Δ {V}_{top} = \frac{BVDSS}{L} x - Δ {V}_{top} for x \geq x\_GPR , \qquad ( 3 )$$

with a first assumption given by equation (4):

$$BVDSS = {BV}_{ideal} = \frac{{b}_{n} L}{ln ( {a}_{n} L )} , where \qquad ( 4 )$$

$${a}_{n} = 7.03 \times 1 {0}^{5} \frac{1}{cm} and {b}_{n =} 1.47 \times 1 {0}^{6} \frac{V}{cm} ,$$

with a second assumption of constant Np producing the following equation (5):

$$Δ {V}_{top} = \frac{q {N}_{D}}{{ε}_{s}} {t}_{drift 1} ( \frac{{ε}_{s}}{{ε}_{ox}} {t}_{ox} + \frac{{t}_{drift 1}}{2} ) \qquad ( 5 )$$

and a third boundary condition assumption for t_{drift} calculation given by the following equation (6):

$$0 < {t}_{drift 1} < \frac{{t}_{drift}}{2} , \qquad ( 6 )$$

where a narrower range is 0.1 μm≤t_{drift1}≤0.4 μm. This yields the following linear equation (7):

$${V}_{FP} ( x ) = \frac{BVDSS}{L} x - \frac{{qN}_{D}}{{ε}_{s}} {t}_{drift 1} ( \frac{{ε}_{s}}{{ε}_{ox}} {t}_{ox} + \frac{{t}_{drift 1}}{2} ) , \qquad ( 7 )$$

A breakdown field estimation at x=L yields the following:

At the surface in Si:

$${E}_{max}^{Si} = \frac{{qN}_{D}}{{ε}_{s}} {t}_{drift 1} \approx 0.55 \frac{MV}{cm} < {E}_{C}^{Si} \approx 0.6 \frac{MV}{cm} ,$$

At the surface in SiO₂:

$${E}_{max}^{SiO 2} = \frac{{qN}_{D}}{{ε}_{ox}} {t}_{drift 1} \approx 1.65 \frac{MV}{cm} < {E}_{C}^{SiO 2} \approx 10 \frac{MV}{cm} ,$$

and

In the bulk semiconductor material: E^{Si}=0@z=tₒₓ+t_{drift1},
where V_{D}=Vₘₐₓ, q is the free electron charge (also referred to as the elementary charge), N_{D} is the dopant concentration of the drift region, GPR is the right edge of the gate poly, tₒₓ is the gate dielectric thickness, t_{drift} is the drift region thickness, Es is the silicon permittivity, εₒₓ is the oxide permittivity (oxide=SiO₂), E^{Si}ₘₐₓ is the critical electric field of silicon, and E^{SiO2}ₘₐₓ is the critical electric field of silicon dioxide.

In one implementation, the modeling and analysis can include or account for band to band tunneling (BTBT) with respect to thin gate dielectric structures. One example uses the following approximation for vertical semiconductor the surface electric field at the gate edge:

$${E}_{BTBT \_ Z} = \frac{{V}_{D} - {V}_{G} - {V}_{FB} - {f}_{S}}{\frac{{ε}_{s}}{{ε}_{ox}} {t}_{ox}} ,$$

where E_{BTBT_z} is a first order approximation for vertical semiconductor surface electric field at the gate edge, and undesired band to band tunneling can occur if the vertical electric field exceeds E_{BTBT_z}. V_{D} is the drain voltage (which can go up to the device breakdown voltage BV with respect to the source in the device off-state, assuming source/back gate is grounded), V_{G} is the gate voltage (e.g., with respect to the source in the off-state), V_{FB} is the flatband voltage that can be approximately 0V for an n+polysilicon gate and n-type Silicon or can be non-zero in other cases. In one example, fₛ can be estimated as “BG/q”, where BG is the band gap energy of the semiconductor (e.g., the band gap energy BG of Silicon is 1.12 eV), and q is the free electron charge, and εₛ, εₒₓ, and tₒₓ are as defined above.

At 204 in FIG. 2, the example implementation of the method 200 includes selection of LDMOS transistor layout and/or process variables for optimization or improvement. The method 200 continues at 206 with creating the device model of the drain extended transistor 101 with the biased field plate 142 based on the analytical modeling, followed by simulating the transistor performance at 208 using the device model. In one example, the transistor device model created at 206 is a process level model, such as a device structure file (e.g., device cross-section), with selected field plate position(s), corresponding field plate bias voltage(s), and may further include device structure elements. In a first iteration, the transistor device performance is simulated at 208 in FIG. 2, for example, with respect to transistor off-state drain-source breakdown voltage BVDSS and on-state transistor drain-source resistance RDSON using the device model. In one example, the simulation is performed using predetermined (e.g., target) field plate position and bias voltage (or more than one bias voltage for the case of multiple biased field plates, such as in FIG. 5 below).

At 210 in FIG. 2, a specific resistance RSP is computed at 210 based on the simulated drain-source resistance RDSON (e.g., extracted from I_{D}-V_{G} plot with a small V_{DS}) and the simulated transistor area (e.g., a distance between a source and drain (e.g., HP in FIG. 1A) multiplied by the transistor width along the second direction Y (e.g., WIDTH in FIG. 1A)). The illustrated example implementation uses a figure of merit or acceptability criterion that is used to assess progressive transistor performance improvement through adjustment of the device model in one or more iterations.

The illustrated implementation includes a determination at 212 as to whether the figure of merit is acceptable. The acceptability criterion used for the decision at 212 can be a figure of merit reaching or exceeding a given target (either increasing past a target, or decreasing past a different target), or exceeding a predetermined number of iterations, or a figure of merit being within a predetermined range that includes a desired target value.

If the final device satisfies the acceptance criteria, the final structure can be provided to circuit designers for circuit simulations, and SPICE modeling can translate the final device a form suitable for circuit simulations. If the figure of merit has not satisfied the acceptance criteria (NO at 212), the method 200 proceeds to 214, at which the device model is adjusted based on the simulation to create an adjusted device model to improve the figure of merit. Any suitable adjustment of one or more aspects of the device model can be implemented at 214, for example, based on the specific type of figure of merit used in assessing acceptability at 212. In one example, the device model adjustment at 214 includes adjusting one or more of a field plate position, a field plate bias voltage VFP, and a device structure or element of the device model based on the simulation to improve the figure of merit. In one example, the figure of merit is computed based on the off-state breakdown voltage BVDSS or the on-state resistance RDSON of the drain extended transistor 101. In this or another example, the figure of merit is computed based on both the off-state breakdown voltage BVDSS and the on-state resistance RDSON of the drain extended transistor 101. In this or a further example, the figure of merit correlates the off-state breakdown voltage BVDSS and the on-state resistance RDSON of the drain extended transistor 101.

In one implementation, the figure of merit is computed as a ratio of the square of a breakdown voltage BVDSS of the drain extended transistor 101 to the specific resistance RSP of the drain extended transistor 101 computed at 210 (e.g., BVDSS²/RSP). In one example, the adjustment at 214 of the device model increases the figure of merit ratio (BVDSS²/RSP) of the drain extended transistor 101. Subsequent simulation is performed at 208 using the adjusted device model. Updated specific resistance information is computed at 210 and the figure of merit is revaluated at 212. In one implementation, the evaluation at 212 determines whether the most recent adjustment at 214 yielded an improvement in the computed figure of merit (e.g., an increase in BVDSS²/RSP). In one example, the evaluation at 212 can include a determination of one or more acceptance conditions, such as comparison of the most recent computed figure of merit with a target value or target range and/or a determination that a maximum number of iterations has occurred, and/or a determination that a local maxima (or local minimum) in the figure of merit has been reached in the most recent or in a previous iteration, indicating that further improvement is unlikely. In the above example, increasing the figure of merit ratio BVDSS²/RSP balances the off-state breakdown voltage of the modeled transistor 101 with the desirability of low on-state drain-source resistance for a given half pitch dimension of the evaluated device design.

Once the acceptance criterion has been met, a circuit model of the transistor can be created based on the updated/adjusted device structure file and circuit level simulation (e.g., SPICE model simulation or modeling of nonlinear circuits with small signal analysis, such as including quiescent point calculation at which the circuit is linearized) can be performed (not shown) using the circuit model of the transistor 101 created at 216, with optional selective readjustment of the device model based on the circuit level simulation, although not a requirement of all possible implementations. In one example, the method 200 can include fabricating an integrated circuit (e.g., semiconductor device 100 above) with a drain extended field plate biased transistor 101 based on the circuit model and/or the device model. The method 200 can be implemented in a variety of different manners, such as modeling breakdown and on-state conduction performance to determine beneficial field plate size and position values given a starting drift length or half pitch dimension, a given gate dielectric oxide thickness top and field plate bias voltage(s).

In another example, a method 200 can be performed given starting drift length or half pitch dimension, a given gate dielectric oxide thickness t_{GD} and field plate dimensions and position values to determine beneficial field plate bias voltage(s). A variety of different approaches can be used, and the illustrated examples provide optimization or at least enhancement of LDMOS characteristics (e.g., BVDSS, RDSON, etc.) based on a desired transistor operating voltage rating, and creation of device and circuit models of the transistor with an approximately linear relationship between drain field plate position(s) and field plate bias voltage(s). Device simulation based on the linear relationship and one or more iterations of simulation and model adjustment can beneficially improve one or more figures of merit for circuit model development of the LDMOS based on multiple distinctive electrical behaviors of the LDMOS transistor 101.

FIG. 2A shows an example method of fabricating a semiconductor device. In one example, the method of FIG. 2A includes formation of the gate electrode 140 and the field plate 142 on a uniform gate dielectric layer 134 (e.g., FIG. 1 above). The individual layers can be of any suitable stoichiometric composition that is or includes the named constituent materials alone or in the further presence of small amounts of impurities, artifacts, or other materials, such as materials that may remain after individual processing steps associated with the manufacturer of semiconductor products.

At 220 in FIG. 2A, a gate dielectric layer is formed to a uniform thickness on or over (e.g., directly on and contacting) a semiconductor layer of a processed wafer. In one example, the gate dielectric layer 134 shown in FIG. 1 is formed over all or select portions of a top side of the semiconductor layer 104. Various implantations (not shown) and other process steps (e.g., formation of shallow trench isolation structures 118) can be done before and/or after the gate dielectric, gate electrode and field plate formation. In one example, the gate dielectric layer 134 is formed at 220 in FIG. 2A to a thickness (e.g., t_{GD1}, t_{GD2} in FIG. 1) of approximately 200 Å or less. In this or another example, the gate dielectric layer 134 is formed at 220 to a thickness t_{GD1}, t_{GD2} of approximately 20 A or more. In these or another example, the gate dielectric layer 134 is formed at 220 by oxidizing all or a portion of the top side of the semiconductor layer 104. In the above or another example, the gate dielectric layer 134 is formed at 220 as a continuous structure of uniform thickness t_{GD1}, t_{GD2} including the first and second portions P1 and P2 as discussed above in connection with FIG. 1. In one implementation, the first and second portions P1 and P2 of the gate dielectric layer 134 are directly on and contacting the semiconductor layer 104 without any field oxide over the drift region 120, as distinct from field oxide approaches.

At 222 and 224 in FIG. 2A, the gate electrode 140 is formed over the first portion P1 of the gate dielectric layer 134 and the field plate 142 is formed over the second portion P2 of the gate dielectric layer 134. In one example, the gate electrode 140 and the field plate 142 are formed by forming (e.g., depositing) a polysilicon layer on the gate dielectric layer 134 at 222 and patterning (e.g., selectively etching) the polysilicon layer at 224 in order to form the gate electrode 140 over the first portion P1 of the gate dielectric layer 134 and the field plate 142 over the second portion P2 of the gate dielectric layer 134. In one example, the gate dielectric layer portions P1 and P2 are separated by an etch process that patterns the polysilicon layer at 224. In other examples, the gate dielectric layer portions P1 and P2 may remain connected after an etch process that patterns the polysilicon layer at 224. In one implementation, the field plate 142 is directly on and contacting the second portion P2 of the gate dielectric layer 134 as shown in FIG. 1. In this or another example, the patterned gate electrode 140 is directly on and contacting the first portion P1 of the gate dielectric layer 134. In one example, the polysilicon is deposited at 222 using any suitable deposition process that forms the polysilicon directly on and contacting an upper portion of the gate dielectric layer 134. Any suitable patterning processing can be used at 224, such as forming and patterning an etch mask over the deposited polysilicon layer to cover the prospective gate electrode and field plate portions thereof, followed by performing one or more etch processes to remove the exposed portions of the polysilicon, leaving the patterned polysilicon gate electrode 140 and field plate 142 as shown in FIG. 1.

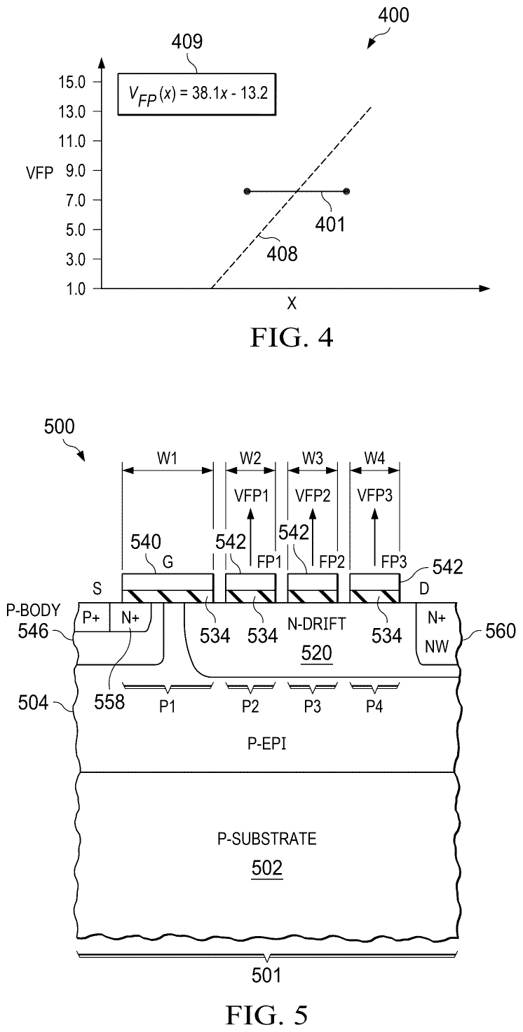

FIG. 4 shows a graph 400 with an ideal linear field plate bias voltage curve 408 (VFP) as a function of lateral distance from the source to the drain along the first direction X. The graph 400 also shows a simulated lateral position as a horizontal bar 401 (e.g., corresponding to the field plate width dimension 161 and the distances 183 and 185 in FIG. 1 above) of a single biased field plate 142 for an example transistor with a voltage rating of 30 V. The graph 400 further shows a linear field plate bias voltage equation 409 (e.g., an implementation of equation (1) above) as a function of the lateral distance or position along the first direction X. The iterative adjustment of the device model to create the circuit model can help ensure that the biased field plate example represented by the bar 401 is positioned along the respective ideal linear analytical model curve 408 and provides off-state electric field uniformity benefits without adversely impacting on-state low resistance and without increasing the transistor half pitch dimension.

FIG. 5 shows another example semiconductor device 500 that includes a drain extended transistor 501 with three biased field plates 542 (e.g., labeled FP1, FP2, and FP3) spaced apart from one another between a gate electrode 540 and the transistor drain D. The device 500 in FIG. 5 includes a p-substrate 502, a body region with p-type epitaxial silicon 504, a p-type implanted body region 546, an n-type drift region 520, as well as a gate dielectric layer 534 with portions P1, P2, P3, and P4 having widths corresponding to (e.g., approximately coextensive with) widths W1, W2, W3, and W4 of the respective gate electrode 540 and field plates 542, a drain 560 and a source S with an implanted region 558, which can be similar in some respects to the respective structures 142, 140, 102, 104, 146, 120, 134, 160, and 158 as illustrated and described above in connection with FIGS. 1 and 1A. In other implementations, any integer number of biased field plates can be used, with corresponding field plate bias voltages to enhance the uniformity of electric field effects during off-state operation of a drain extended transistor, without significantly adversely impacting the desired low on-state resistance (RDSON) and potentially without requiring increase in the half pitch or other dimensions of the drain extended transistor to facilitate high power density and small form factor electronic devices, although increasing the number of field plates can add lateral space and may increase the half pitch in some examples.

In the transistor off state, a single field plate 142 over the gate dielectric layer 134 (e.g., gate oxide, such as SiO₂) can improve the electrostatic control in the drift region. In one example, increased voltage rating can be achieved without increasing the half pitch distance (HP in FIG. 1A above) by increasing the field plate to drain and/or field plate to gate spacing and biasing the field plate 142 at an intermediate potential helps promote optimum charge balance in the drift region to enhance BVDSS. In the off state in one example, equipotential lines escape between gate and the field plate to help relieve drain stress and promote uniform drift region charge balance even when using a small half pitch size dimension for a given breakdown voltage rating of the transistor 101. In the on state, the biased field plate 142 promotes more accumulation of carriers to reduce the RDSON value, and increasing the field plate bias voltage can further RDSON. In operation in the on state, the field plate bias helps to accumulate the channel to reduce the RDSON below what could be achieved with a conventional LDMOS design.

While various examples of the present disclosure have been described above, it should be understood that they have been presented by way of example only and not limitation. Numerous changes to the disclosed examples can be made in accordance with the disclosure herein without departing from the spirit or scope of the disclosure. Thus, the breadth and scope of the present description should not be limited by any of the above described examples. Rather, the scope of the disclosure should be defined in accordance with the following claims and their equivalents. Modifications are possible in the described examples, and other implementations are possible, within the scope of the claims.

What is claimed is:

1. A semiconductor device, comprising:
a drain extended transistor including:
a semiconductor layer over a semiconductor substrate, the semiconductor layer having a body region with a first conductivity type and a drain drift region with a second, opposite, conductivity type;
a gate dielectric layer including first and second portions of a uniform thickness on the semiconductor layer, wherein:
the first portion is located over a junction between the body region and the drain drift region; and
the second portion is located over the drain drift region;
a gate electrode on the first portion of the gate dielectric layer;
a drain region with the second conductivity type in the drain drift region; and
a field plate located on the second portion of the gate dielectric layer and disposed between the gate electrode and the drain region.

2. The semiconductor device of claim 1, further comprising a circuit configured to provide a non-zero field plate bias voltage to the field plate that is different from a voltage of the gate electrode.

3. The semiconductor device of claim 1, wherein the gate dielectric layer includes silicon dioxide having a thickness of approximately 200 Å or less.

4. The semiconductor device of claim 1, wherein the gate electrode and the field plate include polysilicon.

5. A transistor, comprising:
a body region in a semiconductor layer, the body region having a first conductivity type;
a drain drift region in the semiconductor layer, the drain drift region having a second, opposite, conductivity type;
a gate dielectric layer including first and second portions of a uniform thickness on the semiconductor layer, wherein:
the first portion is located over a junction between the body region and the drain drift region; and
the second portion is located over the drain drift region;
a gate electrode on the first portion of the gate dielectric layer;
a drain region in the drain drift region, the drain region having the second conductivity type; and
a field plate located on the second portion of the gate dielectric layer and disposed between the gate electrode and the drain region.

6. The transistor of claim 5, wherein:
the first portion of the gate dielectric layer corresponds to an entire lateral dimension of the gate electrode; and
the second portion of the gate dielectric layer corresponds to an entire lateral dimension of the field plate.

7. The transistor of claim 5, wherein a thickness of the gate dielectric layer is approximately 200 Å or less.

8. The transistor of claim 5, wherein a thickness of the gate dielectric layer is approximately 20 Å or more.

9. The transistor of claim 5, wherein the gate electrode and the field plate includes a same material.

10. The transistor of claim 5, wherein:
the gate dielectric layer includes silicon dioxide; and
the gate electrode and the field plate include polysilicon.

11. The transistor of claim 5, wherein the first and second portions of the gate dielectric layer are spaced apart from one another.

12. The transistor of claim 5, wherein the first portion of the gate dielectric layer is connected to the second portion of the gate dielectric layer.

13. The transistor of claim 5, wherein the field plate is a first field plate, the transistor further comprising:
a second field plate located on a third portion of the gate dielectric layer, wherein the second field plate is disposed between the first field plate and the drain region.

14. The transistor of claim 13, wherein the first and second field plates are located over the drain drift region.

15. The transistor of claim 13, further comprising:
a third field plate located on a fourth portion of the gate dielectric layer, wherein the third field plate is disposed between the second field plate and the drain region.

16. The transistor of claim 5, wherein the first and second portions of the gate dielectric layer are formed concurrently.

17. A method, comprising:
forming a gate dielectric layer of a uniform thickness on a semiconductor layer including a body region and a drain drift region;
forming a polysilicon layer on the gate dielectric layer; and
patterning the polysilicon layer to form a gate electrode over a first portion of the gate dielectric layer and a field plate over a second portion of the gate dielectric layer, wherein:
the first portion is located over a junction between the body region and the drain drift region; and
the second portion is located over the drain drift region.

18. The method of claim 17, wherein forming the gate dielectric layer includes oxidizing a side of the semiconductor layer.

19. The method of claim 17, wherein patterning the polysilicon layer includes patterning the gate dielectric layer to form the first and second portions of the gate dielectric layer.

20. The method of claim 17, further comprising:
coupling the field plate to a circuit configured to provide a non-zero field plate bias voltage to the field plate that is different from a voltage of the gate electrode.
